(19) United States
(12) Patent Application Publication
(10) Pub. No.: US 2012/0240979 A1
(43) Pub. Date: Sep. 27, 2012

(54) SOLAR CELL MODULE AND SOLAR ENERGY GENERATING DEVICE

(75) Inventors: Tsuyoshi Maeda, Osaka (JP); Hidefumi Yoshida, Osaka (JP)

(73) Assignee: SHARP KABUSHIKI KAISHA, Osaka (JP)

(21) Appl. No.: 13/514,283

(22) PCT Filed: Oct. 28, 2010
(86) PCT No.: PCT/JP2010/069160

§ 371 Date: Jun. 6, 2012

(30) Foreign Application Priority Data
Jan. 13, 2010 (JP) 2010-005257

(51) Int. Cl. H01L 31/052

(52) U.S. Cl. 136/247; 136/246

(57) ABSTRACT

To provide a solar power generating and heat collecting system capable of efficient power generation and heat collection with a small-area solar cell element, a solar cell module (10) includes a power generating section (1) and a heat collecting section (4). The power generating section (1) includes: a light guide section (2) having a light receiving surface for receiving light from outside, the light guide section being for guiding light received on the light receiving surface; and a solar cell element (3) provided on an end face intersecting the light receiving surface of the light guide section (2), the solar cell element being for receiving light guided through the light guide section (2). The heat collecting section (4) is provided so as to face an opposite surface opposite the light receiving surface of the light guide section (2). In short, the power generating section (1) and the heat collecting section (4) are stacked on top of each other to constitute the solar cell module (10).

### TECHNICAL FIELD

The present invention relates to a solar cell module and a solar power generating device including the solar cell module.

### BACKGROUND ART

For the purpose of efficient use of solar energy, a typical solar energy generating device has conventionally been configured to collect sunlight with solar panels laid all over a surface to face the sun. In recent years, a solar power generating device has been developed, which enables power generation and heat collection by providing a heat collecting panel in the vicinity of a solar panel to collect sunlight and utilizing the sunlight thus collected.

As a solar power generating device including a heat collecting panel, there has been known a device in which a heat collecting panel is provided (i) on a surface on which a solar panel is provided and (ii) in parallel to the solar panel. Further, there also exists a device that collects heat through a heat collecting panel by (a) stacking the heat collecting panel on a solar panel and (b) collecting heat radiated from the solar panel or converting light having passed through the solar panel (e.g., refer to solar power generating devices described in Patent Literatures 1 through 6).

For example, the solar power generating device described in Patent Literature 1 includes, in the following order, (i) a solar panel, (ii) an infrared radiation selectively transmitting layer that transmits only infrared radiation and reflects visible light, and (iii) a heat collecting electrical insulating layer that converts infrared radiation into heat. This configuration allows the device to (a) generate electric power from visible light incident on the solar panel, (b) collect heat of infrared radiation by allowing the heat collecting electrical insulating layer to absorb the light, which infrared radiation is part of the light having passed through the solar panel and has passed through the infrared radiation selectively transmitting layer, and (c) reuse, in the solar panel, visible light reflected by the infrared radiation selectively transmitting layer to generate electric power.

Further, a solar power generating device described in Patent Literature 2 is configured in the following manner. That is, (i) a top resin layer and (ii) a bottom resin layer that is on a heat collecting panel side and is thinner than the top resin layer are provided so as to sandwich a solar panel so that the amount of heat passing through the bottom resin layer is greater than the amount of heat passing through the top resin layer. This increases heat collection efficiency of the heat collecting panel.

### CITATION LIST

### Patent Literatures

Patent Literature 1

Japanese Patent Application Publication, Tokukaihei, No. 10-110670 A (Publication Date: Apr. 28, 1998)

Patent Literature 2

Japanese Patent Application Publication, Tokukaihei, No. 11-103087 A (Publication Date: Apr. 13, 1999)

Patent Literature 3

Japanese Patent Application Publication, Tokukaihei, No. 11-152868 A (Publication Date: Jun. 8, 1999)

Patent Literature 4

Japanese Patent Application Publication, Tokukaihei, No. 11-330525 A (Publication Date: Nov. 30, 1999)

Patent Literature 5

Japanese Patent Application Publication, Tokukai, No. 2006-78006 A (Publication Date: Mar. 23, 2006)

Patent Literature 6

Japanese Patent Application Publication, Tokukai, No. 2008-151490 A (Publication Date: Jul. 3, 2008)

### SUMMARY OF INVENTION

### Technical Problem

Conventional solar panels used for solar power generation are typically constituted by opaque semiconductors and therefore cannot be placed on top of each other. Therefore, a large-area solar panel is required in order to collect a sufficient amount of sunlight. The solar power generating devices described in Patent Literatures 1 through 6 are configured such that the solar panels are laid all over a light receiving surface, and therefore require many solar panels that correspond to the area of the light receiving surface. Further, in order to achieve sufficient power generation efficiency and heat collection efficiency, the area of the light receiving surface needs to be large, and, as the area of the light receiving surface increases, a larger number of solar panels become necessary.

The present invention has been made in view of the foregoing problem, and it is an object of the present invention to provide a solar power generating and heat collecting system that is small in area but is capable of efficient power generation and heat collection.

### Solution to Problem

In order to attain the above object, a solar cell module in accordance with the present invention includes: a power generating section including (i) a light guide section having a light receiving surface for receiving light from outside, the light guide section being for guiding light received on the light receiving surface and (ii) a solar cell element provided on an end face that intersects the light receiving surface of the light guide section, the solar cell element being for receiving light guided through the light guide section; and a heat collecting section provided so as to face a back surface opposite to the light receiving surface of the light guide section. A solar power generating device in accordance with the present invention includes the solar cell module in accordance with the present invention.

According to the configuration, the solar cell module is capable of efficiently generating power and collecting heat from sunlight. Since the solar cell element may be provided on the end face of the light guide section, it is not necessary that solar cell elements be laid all over the light receiving surface, and a large amount of electric power can be obtained with use of a small-area solar cell element. Further, the solar cell module utilizes light that passes through the light guide section, which light is not used for power generation, by receiving such light and converting the light into thermal energy in the light collecting section. This makes it possible to provide a highly efficient solar power generating and heat collecting system. Furthermore, since the solar cell module is configured such that the power generating section and the heat collecting section are stacked on top of each other, the solar cell module is capable of efficiently utilizing heat radiated from the power generation section because the heat collecting section efficiently absorbs the heat radiated from the power generating section. This makes it possible to improve heat collection efficiency in the heat collecting section while preventing an increase in temperature of the power generating section.

### Advantageous Effects of Invention

A solar cell module in accordance with the present invention includes: a power generating section including (i) a light guide section having a light receiving surface for receiving light from outside, the light guide section being for guiding light received on the light receiving surface and (ii) a solar cell element provided on an end face that intersects the light receiving surface of the light guide section, the solar cell element being for receiving light guided through the light guide section; and a heat collecting section provided so as to face a back surface opposite to the light receiving surface of the light guide section. This makes it unnecessary for the solar cell module to have solar cell elements laid all over the light receiving surface, thereby making it possible to provide a solar power generating and heat collecting system that is small in area but is capable of efficient power generation and heat collection.

### BRIEF DESCRIPTION OF DRAWINGS

FIG. 1

FIG. 1 is a view schematically showing a solar cell module in accordance with an embodiment of the present invention.

FIG. 2

FIG. 2 is a view describing an example of a power generating section of a solar cell module in accordance with the present invention.

FIG. 3

FIG. 3 is a view describing another example of a power generating section of a solar cell module in accordance with the present invention.

FIG. 4

FIG. 4 is a view describing a further example of a power generating section of a solar cell module in accordance with the present invention.

### DESCRIPTION OF EMBODIMENTS

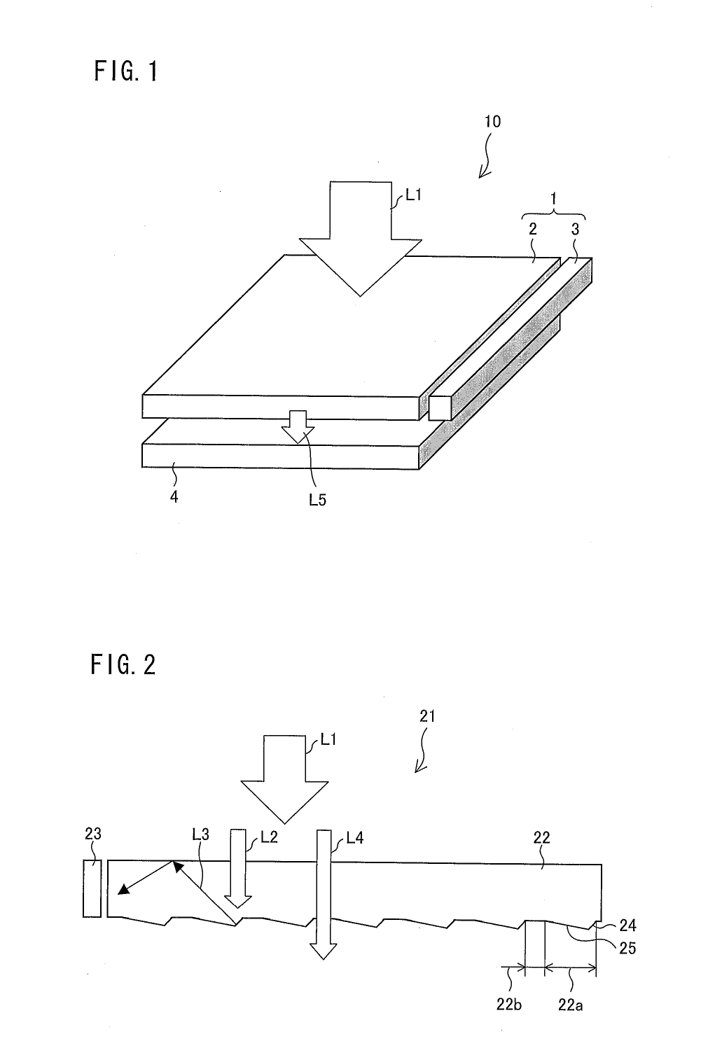

An embodiment of a solar cell module 10 in accordance with the present invention is described below with reference to FIGS. 1 through 4. FIG. 1 is a view schematically showing the solar cell module 10 in accordance with an embodiment of the present invention. FIGS. 2 through 4 are views each describing an example of a power generating section of the solar cell module 10. As shown in FIG. 1, the solar cell module 10 includes a power generating section 1 and a heat collecting section 4. The power generating section 1 includes (i) a light guide section 2 having a light receiving surface for receiving light from outside, which light guide section guides the light received at the light receiving surface and (ii) a solar cell element 3 provided on an end face intersecting the light receiving surface of the light guide section 2, which solar cell element receives light guided through the light guide section 2. The heat collecting section 4 is provided so as to face a back surface of the light guides section 2, which back surface is opposite to the light receiving surface. In other words, the power generating section 1 and the heat collecting section 4 are stacked on top of each other so as to constitute the solar module 10.

[Solar Cell Module 10]

The solar cell module 10 is capable of efficiently converting solar energy into electric power or heat when included in a solar power generating device and the solar power generating device including the solar cell module 10 is provided on a window or roof of a building, an automobile window, or the like. The solar cell module 10 does not need to have solar cell elements 3 laid all over the light receiving surface, and is capable of efficiently generating power and collecting heat despite its small area. This makes it possible to provide a highly efficient solar power generating and heat collecting system.

It should be noted that the solar power generating device may, for example, include a plurality of solar cell modules 10, and, in addition, (i) a battery for storing electric power generated in the power generating section 1 and (ii) a heat storage section for storing heat absorbed through the heat collecting section 4.

[Power Generating Section 1]

The power generating section 1 is configured to (i) guide, through the light guide section 2 towards the solar cell element 3, light (indicated by the arrow L1 in FIG. 1) received through the light receiving surface of the light guide section 2 and (ii) generate electric power in the solar cell element 3 which receives the light thus guided.

(Light Guide Section 2)

The light guide section 2 is not limited, provided that it (i) diffuses light that it received through the light receiving surface and (ii) causes the light to be collected to the solar cell element 3 provided on the end face. As the light guide section 2, a well-known board or sheet can be used. Examples of such a board include, but are not limited to, an acrylic board, a glass board, a polycarbonate board, and the like. An example of such a sheet is, but is not limited to, a film made of acrylic resin. The thickness of the light guide section 2 is not particularly limited, but is preferably equal to or greater than a visible light wavelength, that is, 1 μm or greater. Further, the thickness is preferably 10 cm or less in view of the weight of the light guide section 2 and the area of the solar cell provided on the end face.

In the case where the solar power generating device including the solar cell module 10 is to be attached to a window frame of a building, the light guide section 2 is constituted by an acrylic board etc. having such a size and thickness that enable the acrylic board to be fitted to the window frame and to function as a windowpane. In the case where the solar power generating device is to be provided on a roof, the size and the thickness of the light guide section 2 may be suitably arranged depending on conditions such as installation area. The light guide section 2 preferably has the shape of a rectangular parallelepiped, but may have a wedge shape.

A board or a sheet to be used as the light guide section 2 can be obtained by dispersing therein a fluorescent material that diffuses light entering the light guide 2 through the light receiving surface. Examples of such fluorescent materials to be dispersed in the board or sheet include rare-earth metal complexes. Examples of such rare-earth metal complexes include, but are not limited to, sialon fluorescent materials such as a [Tb(bpy)2]C13 complex, a [Tb(terpy)2]C13 complex, a [Eu(phen)2]C13 complex, and Ca-α-SiAlON:Eu. It is also possible to use (i) a hydrochloride or sulfate salt of a rare-earth metal such as samarium, terbium, europium, gadolinium, or dysprosium, (ii) a transition metal acid salt such as calcium molybdate or calcium tungstate, (iii) an aromatic hydrocarbon such as benzene and naphthalene, (iv) a phthalein pigment such as eosin and fluorescein, or (v) the like. Alternatively, a coumarin fluorescent pigment may be used as the fluorescent material.

(Solar Cell Element 3)

As the solar cell element 3, a known solar cell can be used. Examples of a known solar cell include, but are not limited to, an amorphous silicon (a-Si) solar cell, a polycrystalline silicon solar cell, and a monocrystalline silicon solar cell etc. The solar cell element 3 is attached, with a well-known transmissive adhesive or a fastener, to an end face intersecting the light receiving surface of the light guide section 2. Although the solar cell element 3 is not particularly limited in its size, it is preferable that the width of a light receiving part of the solar cell element 3 be equal to the thickness of the light guide section 2. This makes it possible for the solar cell element 3 to efficiently receive light that has been guided through the light guide section 2 and then has reached the end face of the light guide section 2. In addition, there is no particular limitation on how many solar cell element(s) 3 to provide.

[Heat Collecting Section 4]

The heat collecting section 4 receives light (indicated by the arrow L5 in FIG. 1) having passed through the light guide section 2, and converts the light into thermal energy. The heat collecting section 4 may be configured to absorb heat emitted and transferred from the power generating section 1. As such a heat collecting section 4, a well-known energy collector such as a solar energy water heater can be used. Further, in order to utilize the absorbed heat, the heat collecting section 4 may include a water-flow pipe through which a heat exchange medium such as water flows. Further, the heat collecting section 4 may include a heat storage section for storing the absorbed heat.

Out of incident light having entered the light guide section 2 through the light receiving surface, ultraviolet radiation and short-wavelength visible light are absorbed by the fluorescent material dispersed in the light guide section 2. The fluorescent material emits excitation light upon excitation by absorption of light, and the excitation light is guided through the light guide section 2 and is collected to the solar cell element 3 where the light is used for power generation. On the other hand, out of the incident light having entered the light guide section 2 through the light receiving surface, long-wavelength visible light, near-infrared radiation and infrared radiation pass through the light guide section 2. Since the solar cell module 10 is configured such that the heat collecting section 4 is stacked on the back surface side of the light guide section 2 which back surface is opposite to the light receiving surface, the light having passed through the light guide section 2 enters the heat collecting section 4 where it is converted into thermal energy. This enables efficient heat collection.

A solar cell module 10 as shown in FIG. 1 was prepared, and its electric power generation was measured. First, an acrylic plate (10 mm thick, 200 cm×200 cm in area) was prepared by dispersing, in acrylic resin, approximately 5% by weight of a rare-earth metal complex (a [Tb(bpy)2]C13 complex, a [Tb(terpy)2]C13 complex, and/or a [Eu(phen)2]C13 complex etc.), which rare-earth metal complex (i) emits light upon irradiation with sunlight and (ii) has a particle size in the range of 5 μm to 10 μm. The acrylic plate thus prepared was used as the light guide section 2. The solar cell element 3 having a 10 mm-wide light receiving section was provided on an end face of the light guide section 2, and aluminum reflecting plates were bonded to the other end faces (3 surfaces). In this way, the power generating section 1 was prepared. A water heater (heat collecting section 4) was provided on a back surface side of the power generating section 1, which back surface was opposite to the light receiving surface.

According to the solar cell module 10, out of incident light having entered the solar cell module 10 through the light receiving surface, ultraviolet radiation and short-wavelength visible light are absorbed by the fluorescent material dispersed in the light guide section 2. The fluorescent material emitted light having a yellowish green wavelength upon excitation by absorption of light. Approximately 60% of this light was guided through the light guide section 2 and was collected to the solar cell element 3 where the light was used for power generation. On the other hand, out of the incident light having entered the solar cell module 10 through the light receiving surface, long-wavelength visible light, near-infrared radiation, and infrared radiation, which have passed through the light guide section 2, were converted into thermal energy in the heat collecting section 4. Electricity generated by this solar cell module 10 was 300 W.

Further, another solar cell module 10 including as the light guide section 2 a board obtained by dispersing a coumarin fluorescent pigment in acrylic resin was prepared, and electric power generation was measured. First, an acrylic plate (10 mm thick, 200 cm×200 cm in area) was prepared by dispersing approximately 10% by weight of the coumarin fluorescent pigment in acrylic resin. The acrylic plate thus prepared was used as the light guide section 2. The solar cell element 3 having a 10 mm-wide light receiving section was provided on an end face of the light guide section 2, and aluminum reflecting plates were bonded to the other end faces (3 surfaces). In this way, the power generating section 1 was prepared. A water heater (heat collecting section 4) was provided on a back surface side of the power generating section 1, which back surface was opposite to the light receiving surface.

In the another solar cell module 10, approximately 60% of light that the fluorescent material emitted upon excitation by incident light having entered the solar cell module 10 through the light receiving surface was guided through the light guide section 2 and was collected to the solar cell element 3. On the other hand, light having entered the solar cell module 10 through the light receiving surface and passed through the light guide section 2 was converted into thermal energy in the heat collecting section 4. Electricity generated by this solar cell module 10 was 400 W.

As described above, since the solar cell module 10 includes (i) the power generating section 1 including the light guide section 2 and the solar cell element 3 provided on the end face of the light guide section 2 and (ii) the heat collecting section 4, the solar cell module 10 is capable of efficiently generating power and collecting heat from sunlight. Since the solar cell element 3 may be provided on the end face of the light guide section 2, it is not necessary that solar cell elements be laid all over the light receiving surface, and a large amount of electric power can be obtained with use of a small-area solar cell element 3.

Further, the solar cell module 10 utilizes light that passes through the light guide section 2, which light is not used for power generation, by receiving such light and converting the light into thermal energy in the light collecting section 4. This makes it possible to provide a highly efficient solar power generating and heat collecting system. Furthermore, since the solar cell module 10 is configured such that the power generating section 1 and the heat collecting section 4 are stacked on top of each other, the solar cell module 10 is capable of efficiently utilizing heat radiated from the power generating section 1 because the heat collecting section 4 efficiently absorbs the heat. This makes it possible to improve heat collection efficiency in the heat collecting section 4 while preventing an increase in temperature of the power generation section 1.

In the following, another embodiment of a specific configuration of the power generating section of the solar cell module is described with reference to FIGS. 2 through 4. It should be noted that although a solar cell element is provided at a distance from an end face of a light guide section for convenience of description in FIGS. 2 through 4, the solar cell module is configured such that the solar cell element is in contact with the end face of the light guide section.

[Embodiment 1 of Power Generating Section]

Embodiment 1 of a power generating section is described with reference to FIG. 2. As shown in FIG. 2, a power generating section 21 includes a light guide section 22 and a solar cell element 23. The light guide section 22 has, on a back surface opposite a light incident surface (light receiving surface) on which light indicated by the arrow L1 is incident, (i) traveling direction changing parts 22a that change a direction of light from the light receiving surface and (ii) transmitting parts 22b that transmit the light from the light receiving surface. It should be noted that the solar cell module including the power generating section 21 is configured such that a heat collecting section is provided so as to face the surface (back surface) on which the traveling direction changing parts 22a and the transmitting parts 22b of the light guide sections 22 are provided.

Each of the traveling direction changing parts 22a has (i) a first inclined surface 24 that reflects the light from the light receiving surface and (ii) a second inclined surface 25 that is inclined towards a direction opposite to the first inclined surface. An angle between the second inclined surface 25 and the back surface is smaller than an angle between the first inclined surface 24 and the back surface. Further, the solar cell element 23 is provided on a surface of the light guide section 22, which surface is one of the surfaces intersecting the light receiving surface of the light guide section 22 and is closer to the second inclined surface 25 than to the first inclined surface 24.

The light guide section 22 is not limited, provided that it (i) guides light having entered the light guide section 22 through the light receiving surface and (ii) causes the light to be collected to the solar cell element 23 provided on an end face. The light guide section 22 can be for example a well-known board such as an acrylic board, a glass board, or a polycarbonate board.

The traveling direction changing parts 22a provided on the back surface of the light guide section 22 change a direction of the light having entered the light guide section 22 through the light receiving surface so that the light will be collected to the solar cell element 23 provided on the end face. The traveling direction changing parts 22a are provided so as to protrude out of the back surface of the light guide section 22. The traveling direction changing parts 22a may be constituted by arranging, on the back surface either in a striped pattern or in a random manner, a plurality of triangular prisms or triangular pyramids extending in a direction parallel to the end face of the light guide section 22. Alternatively, the traveling direction changing parts 22a may be prism-shaped protrusions having the same shape and constituted by (i) the respective first inclined surfaces 24 inclined towards the same direction and (ii) the respective second inclined surfaces 25 inclined towards the same direction. Furthermore, each of the traveling direction changing parts 22a may have an asymmetric cross section with a round tip when cut along a plane perpendicular to the back surface and to the end face.

The first inclined surface 24 of each of the traveling direction changing parts 22a is a reflective surface that reflects, preferably totally reflects, light having traveled from the light receiving surface and reached the first inclined surface 24 (indicated by the arrow L2 in FIG. 2), and is an inclined surface inclined with respect to the back surface. The light incident on and reflected by the first inclined surface 24 (indicated by the arrow L3 in FIG. 2) is guided through the light guide section 22 and collected to the solar cell element 23. The second inclined surface 25 is an inclined surface that is inclined at a smaller angle to the back surface than the first inclined surface 24 is. This makes it possible to guide the light reflected by the first inclined surface 24 through the light guide section 22 and collect the light to the solar cell element 23, while preventing the light from reaching and being scattered by the second inclined surface 25.

Specifically, the angle of inclination of the first inclined surface 24 is set so that the first inclined surface 24 can reflect the light having entered the light guide section 22 through the light receiving surface, and the angle of inclination of the second inclined surface 25 is set to be smaller than the angle of inclination of the first inclined surface 24 so that the light reflected by the first inclined surface 24 will not reach the second inclined surface 25. Accordingly, each of the traveling direction changing parts 22a has a triangular cross section when cut along the plane perpendicular to the back surface and to the end face, and has an asymmetric shape protruding out of the back surface.

The traveling direction changing parts 22a are made from the same material as the light guide section 22, and can be formed by cutting the back surface of the light guide section 22. Alternatively, the traveling direction changing parts 22a may be formed by (i) filling, with a material for the light guide section 22, a mold that can form the traveling direction changing parts 22a of a predetermined shape on the light guide section 22 and (ii) curing the material. The traveling direction changing parts 22a may be formed on the back surface of the light guide section 22 either in a form of protrusions or in a form of indentations.

The transmitting parts 22b provided on the back surface of the light guide section 22 (i) are configured to transmit the light having entered the light guide section 22 through the light receiving surface (indicated by the arrow L4 in FIG. 2), (ii) are constituted by flat areas, and (iii) are areas of the back surface in which areas no traveling direction changing parts 22a are provided. In other words, the transmitting parts 22b and the back surface of the light guide section 22 share the same flat surface. Since the transmitting parts 22b transmit part of the light having entered the light guide section 22, the light guide section 22 looks almost transparent when viewed from the back surface side.

As has been described, the power generating section 21 has, on the back surface of the light guide section 22, the traveling direction changing parts 22a and the transmitting parts 22b. This makes it possible to efficiently (i) guide, through the light guide section 22, the light having entered the light guide section 22 through the light receiving surface and (ii) cause the light to be collected to the solar cell element 23, and thus possible to efficiently generate power. Since the solar cell element 23 is provided on a surface intersecting the light receiving surface of the light guide section 22, the power generating section 21 is capable of achieving sufficient power generation efficiency despite its small area and being produced inexpensively.

Furthermore, the power generating section 21 may be constituted by (i) preparing a light transmissive film (film) on which the traveling direction changing parts 22a and the transmitting parts 22b are formed and (ii) bonding, with a light transmissive adhesive, the light transmissive film to the light guide section 22. Note here that such a power generation section 21 is configured so that a refractive index n(a) of the adhesive and a refractive index n(s) of the light guide section 22 satisfy n(a)≦n(s), and, more preferably, satisfy n(a)<n(s). Further, it is also possible to configure the power generating section 21 such that the n(s), the n(a), and a refractive index n(f) of the light transmissive film satisfy n(f)≦n(a)≦n(s). This suppresses reflection of light by the interface between the adhesive and the light transmissive film, which light has entered the light guide section 22 through the light incident surface and reflected by the traveling direction changing parts 22a.

Further, the power generating section 21 may include a plurality of light guide sections 22 stacked on top of each other so that the back surface of each light guide section 22 faces the light receiving surface of an adjacent light guide section 22. Note here that the solar cell element 23 is provided in a corresponding position of each of the light guide sections 22. This improves power generation efficiency of the power generating section 21. In particular, with the arrangement in which the light guide sections 22 are stacked on top of each other so that the traveling direction changing parts 22a and the transmitting parts 22b of one light guide section 22 are out of alignment with those of other light guide sections 22, it is possible to achieve the following. That is, even if light having entered a first light guide section 22 through its light receiving surface traveled out through the back surface of the first light guide section 22, the light can be reflected by the back surface of a second or any subsequent light guide section 22 and be collected to a corresponding solar cell element 23.

[Embodiment 2 of Power Generating Section]

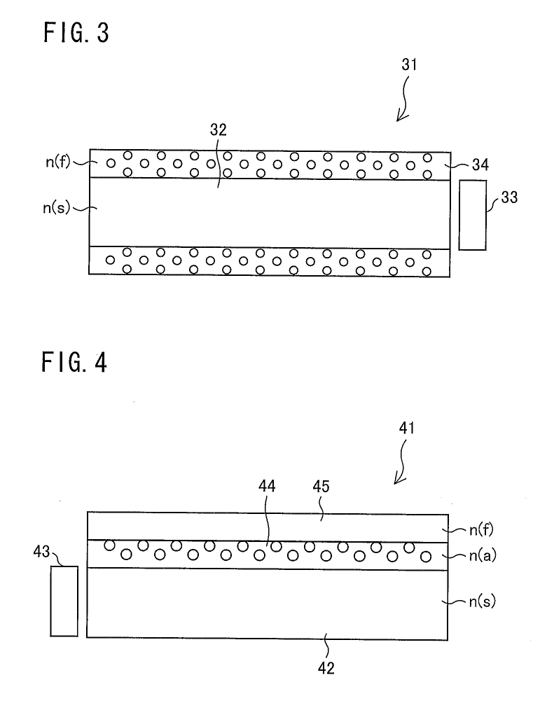

Embodiment 2 of the power generating section is described with reference to FIG. 3. As shown in FIG. 3, a power generating section 31 includes a light guide section 32, a solar cell element 33, and fluorescent material dispersion films 34 each containing a fluorescent material. One of the fluorescent material dispersion films 34 is bonded, via an adhesive, to a light receiving surface (front surface) of the light guide section 32, which light receiving surface receives sunlight. Likewise, the other of the fluorescent material dispersion films 34 is bonded, via an adhesive, to a surface opposite the light receiving surface of the light guide section 32. That is, the power generating section 31 is configured such that the two fluorescent material dispersion films 34 sandwich the light guide section 32.

It should be noted that, although a fluorescent material dispersion film 34 may be bonded only to the light receiving surface, it is preferable to bond fluorescent material dispersion films 34 to both the surfaces because bonding the fluorescent material dispersion films 34 to both the surfaces improves efficiency of power generation from sunlight. Further, the solar cell element 33 is provided on a surface (end face) intersecting the light receiving surface of the light guide section 32. A plurality of solar cell elements 33 may be provided on all of the four surfaces intersecting the light receiving surface.

The light guide section 32 is not limited, provided that it (i) diffuses light having entered the light guide section 32 through the light receiving surface and (ii) causes the light to be collected to the solar cell element 33 provided on the end face. The light guide section 32 can be for example a well-known board such as an acrylic board, a glass board, or a polycarbonate board. Since the light guide section 32 is provided for receiving light and guiding the light therethrough, the light guide section 32 is preferably a transparent plate containing no fluorescent materials. Note, however, that the light guide section 32 is not limited, provided that it has been produced without dispersing therein a fluorescent material etc. in the production process, which fluorescent material is intended for wavelength conversion in the light guide section 32.

A fluorescent material dispersion film 34 is a film obtained by dispersing a fluorescent material in a light transmissive polymer material such as resin, which film is configured to convert the wavelength of light having entered the fluorescent material dispersion film 34 into a wavelength in a range effective for photoelectric conversion carried out by the solar cell element 33. As such a fluorescent dispersion film 34, a well-known film can be used. The fluorescent material dispersion film 34 is for example, but is not limited to, a film obtained by dispersing a fluorescent material in resin such as acrylic resin, polypropylene resin, cycloolefin resin, polycarbonate resin, triacetylcellulose resin, or PET resin.

The fluorescent material to be dispersed in the fluorescent material dispersion film 34 can be, for example, the same fluorescent material as described earlier. It is preferable that the fluorescent material have a particle size in the range of 5 μm to 10 μm. This makes it possible to achieve efficient fluorescence emission. Further, it is preferable that the content of the fluorescent material in the fluorescent material dispersion film 34 be less than or equal to 10% by weight. This makes it possible to suppress multiple scattering and quenching of light by the fluorescent material and to thereby achieve efficient fluorescence emission.

The power generating section 31 is configured such that a refractive index n(s) of the light guide section 32 and a refractive index n(f) of the fluorescent material dispersion film 34 satisfy n(f)≦n(s), and more preferably satisfy n(f)<n(s). This prevents light having entered the fluorescent material dispersion film 34 from being totally reflected by the interface between the fluorescent material dispersion film 34 and the light guide section 32, and therefore makes it possible to efficiently guide the light through the light guide section 32.

When light from a high refractive index region enters a low refractive index region, the light is totally reflected, depending on the angle of incidence. Using an example of the power generating section 31, in the light guide section (an acrylic board) 32 having a refractive index of 1.5, light from the fluorescent material will be emitted out of the light guide section 32 if the light is incident on a surface of the light guide section 32 at an angle of 0° to approximately 41° (assuming that the angle of line normal to the surface is 0°). On the other hand, the light incident at an angle equal to or more than approximately 41° is guided through the light guide section 32 and totally reflected repeatedly. In the case of using such an acrylic board having a refractive index of 1.5 as the light guide section 32, the ratio of the light guided through the light guide section 32 to the light emitted out of the light guide section 32 is approximately 75:25.

As described above, the power generating section 31 makes it unnecessary to disperse a fluorescent material in the light guide section 32, and uses the fluorescent material dispersion film 34 which can be inexpensively produced. This can achieve a reduction in production costs. Furthermore, since the solar cell element 33 is provided on the end face intersecting the light receiving surface of the light guide section 32, the power generating section 31 can achieve sufficient power generation efficiency despite its small area and be inexpensively produced. In addition, since the relationship between the refractive index of the light guide section 32 and the refractive index of the fluorescent material dispersion film 34 is controlled, light that the fluorescent material emitted upon excitation by sunlight can be efficiently guided through the light guide section 32.

Moreover, the power generating section 31 may include a light transmissive adhesive layer between the light guide section 32 and the fluorescent material dispersion film 34 and to thereby bond the light guide section 32 to the fluorescent material dispersion film 34. Note here that the power generating section 31 is configured such that (i) a refractive index n(a) of the adhesive layer, and (ii) the n(s) and the n(f) satisfy n(f)≦n(a)≦n(s). This suppresses reflection at the interface due to the adhesive layer, and makes it possible to efficiently guide sunlight through the light guide section 32.

Further, in the power generating section 31, the thickness, of the light guide section 32, in a direction intersecting a surface to which the florescent dispersion film 34 is bonded may be thicker in an end part than in a central part of the light guide section 32. That is, the light guide section 32 may be tapered from both end parts towards the central part. This makes it easy to attach the solar cell element 33.

In addition, the fluorescent material dispersion film 34 of the power generating section 31 may contain a fluorescent material whose maximum fluorescence wavelength is substantially equal to the wavelength to which the solar cell element 33 is most sensitive. This achieves efficient photoelectric conversion. Further, the fluorescent material dispersion film 34 may be constituted by a stack of films containing fluorescent materials having respective different light absorption wavelengths. Note here that the fluorescent material dispersion film 34 is configured such that the plurality of films each contain a fluorescent material having a maximum fluorescent wavelength substantially equal to the wavelength to which the solar cell element 33 is most sensitive. This makes it possible to convert light in various wavebands into light having a wavelength within the sensitivity range of the solar cell element 33, and thus possible to improve power generation efficiency.

Further, the power generating section 31 may have the fluorescent film 34 provided either over the entire light receiving surface of the light guide section 32 or on part of the light receiving surface. This (i) improves designability of the power generating section 31 and (ii) reduces a chance that light guided through the light guide section 32 collides with the fluorescent material, thereby making it possible to efficiently guide the light and thus improving power generation efficiency.

It should be noted that, according to the power generating section 31, the fluorescent film 34 may be replaced with a fluorescent material layer formed by applying a light transmissive material containing a fluorescent material to a surface of the light guide section 32. In this case, the light transmissive material in which a fluorescent material is to be dispersed may be a high refractive index material, and the fluorescent material layer formed from the high refractive index material may be coated with a low refractive index material layer having a lower refractive index than that of the high refractive index material and serving as a protective layer.

[Embodiment 3 of Power Generating Section]

Embodiment 3 of the power generating section is described with reference to FIG. 4. As shown in FIG. 4, a power generating section 41 includes a light guide section 42, a solar cell element 43, an adhesive layer 44 containing a fluorescent material, and a light transmissive film 45. The light transmissive film 45 is bonded, via the adhesive layer 44, to a light receiving surface (front surface) of the light guide section 42 on which surface sunlight is incident. Further, another light transmissive film 45 may be bonded, via an adhesive layer 44, to a surface opposite the light receiving surface of the light guide section 42. The solar cell element 43 is provided on an end face of the light guide section 42, which end face intersects the light receiving surface. A plurality of solar cell elements 43 may be provided on all of the four end faces intersecting the light receiving surface.

The adhesive layer 44 is a layer obtained by dispersing a fluorescent material in a light transmissive adhesive, which layer converts a wavelength of light having entered the adhesive layer 44 into a wavelength in a range effective for photoelectric conversion carried out in the solar cell element 43. The adhesive layer 44 can be the one obtained by dispersing a fluorescent material in a well-known light transmissive adhesive such as an acrylic adhesive etc., but is not limited to this. Other examples that can be suitably used as the adhesive layer 44 include adhesives each of which is obtained by dispersing a fluorescent material in an α-olefin adhesive, a urethane resin adhesive, an epoxy resin adhesive, an ethylene-polyvinyl acetate resin adhesive, a silicon adhesive, or the like.

The fluorescent material to be dispersed in the adhesive layer 44 can be for example the same fluorescent material as described earlier. It is preferable that the fluorescent material have a particle size in the range of 5 μm to 10 μm. This makes it possible to achieve efficient fluorescence emission. Further, it is preferable that the content of the fluorescent material in the adhesive layer 44 be less than or equal to 10% by weight. This makes it possible to suppress multiple scattering and quenching of light by the fluorescent material and thus possible to achieve efficient fluorescence emission.

The light transmissive film 45 is not limited, provided that it transmits light incident on the light transmissive film 45. Examples of a film that can be used as the light transmissive film 45 include a well-known light transmissive film such as a film made of acrylic resin, polypropylene resin, cycloolefin resin, polycarbonate resin, triacetyl cellulose resin, or PET resin.

The power generating section 41 is configured such that a refractive index n(a) of the adhesive layer 44 and a refractive index n(s) of the light guide section 42 satisfy n(a)≦n(s), and, more preferably, satisfy n(a)<n(s). This prevents light having entered the power generating section 41 from being totally reflected at the interface between the light guide section 42 and the adhesive layer 44, and thus makes it possible to efficiently guide the light through the light guide section 42.

Further, the power generating section 41 can be configured such that the n(s), the n(a), and a refractive index n(f) of the light transmissive film 45 satisfy n(a)≦n(f), and n(a)≦n(s). This makes it possible to suppress reflection at the interface between the adhesive layer 44 and the light transmissive film 45, and thus possible to guide sunlight efficiently so that the light is collected to the solar cell element 43.

The power generating section 41 uses, instead of a light guide plate in which a fluorescent material is dispersed, the adhesive layer 44 which can be inexpensively produced and which has a fluorescent material dispersed therein. This allows a reduction in production costs. Further, since the fluorescent material is to be contained in the adhesive layer 44, it is easy to mix the fluorescent material and thus possible to easily form the adhesive layer 44 that can function as a fluorescent layer. Furthermore, since the solar cell element 43 is provided on the end face intersecting the light receiving surface of the light guide section 42, the power generating section 41 can achieve sufficient power generation efficiency despite its small area and be inexpensively produced. In addition, since the relationship between the refractive index of the light guide section 42 and the refractive index the adhesive layer 44 is controlled, light that the fluorescent material emitted upon excitation by sunlight can be efficiently guided through the light guide section 42.

Further, in the power generating section 41, the thickness, of the light guide section 42, in a direction intersecting a surface to which the adhesive layer 44 is bonded may be thicker in an end part than in a central part of the light guide section 42. That is, the light guide section 42 may be tapered from both end parts towards the central part. This makes it easy to attach the solar cell element 43.

Moreover, the power generating section 41 may have a plurality of light guide sections 42, adjacent ones of which are bonded with the adhesive layer 44.

Further, the power generating section 41 may be configured such that the adhesive layer 44 contains a fluorescent material whose maximum fluorescence wavelength is substantially equal to the wavelength to which the solar cell element 43 is most sensitive. This achieves efficient photoelectric conversion. Further, the adhesive layer 44 may be constituted by a stack of films containing fluorescent materials having respective different light absorption wavelengths. Note here that the adhesive layer 44 is configured such that the plurality of films each contain a fluorescent material having a maximum fluorescent wavelength substantially equal to the wavelength to which the solar cell element 43 is most sensitive. This makes it possible to convert light in various wavebands into light having a wavelength within the sensitivity range of the solar cell element 43, and thus possible to improve power generation efficiency.

Further, the power generating section 41 may have the adhesive layer 44 provided either over the entire light receiving surface of the light guide section 42 or on part of the light receiving surface. This (i) improves designability of the power generating section 31 and (ii) reduces a chance that light guided through the light guide section 42 collides with the fluorescent materials, thereby making it possible to efficiently guide the light and thus improving power generation efficiency.

The present invention is not limited to the description of the embodiments above, but may be altered by a skilled person within the scope of the claims. An embodiment based on a proper combination of technical means disclosed in different embodiments is encompassed in the technical scope of the present invention.

A solar cell module in accordance with the present invention is preferably configured such that the light guide section has, on at least one surface that intersects the end face on which the solar cell element is provided, a fluorescent layer containing a fluorescent material. In other words, it is preferable that the light guide section have, on the light receiving surface and/or the opposite surface of the light guide section, the fluorescent layer containing a fluorescent material. Further, the solar cell module in accordance with the present invention is preferably configured such that the fluorescent layer is a light transmissive film containing a fluorescent material or an adhesive layer containing a fluorescent material.

According to the configuration, since the fluorescent material is dispersed in the light transmissive film or in the adhesive layer and the light transmissive film or the adhesive layer thus obtained is attached to the light guide section, it is (i) unnecessary to prepare a light guide plate having a fluorescent material dispersed therein and (ii) possible to freely carry out patterning and/or to stack the light transmissive film or the adhesive layer. Further, since the solar cell element is provided on a surface intersecting the light receiving surface of the light guide section, the solar cell module can achieve sufficient power generation efficiency despite its small area. As has been described, the configuration makes it possible to provide a solar cell module that provides a high degree of freedom in design and can be inexpensively and easily produced, while maintaining sufficient power generation efficiency.

Further, the solar cell module in accordance with the present invention is preferably configured such that the fluorescent layer is formed by coating said at least one surface of the light guide section with a light transmissive material containing the fluorescent material.

According to the configuration, the fluorescent layer can be formed merely by coating the surface of the light guide section with the light transmissive material containing the fluorescent material. This makes it possible to inexpensively and easily configure the solar cell module.

Further, the solar cell module in accordance with the present invention is preferably configured such that: the light guide section has, on the back surface opposite to the light receiving surface, (i) a traveling direction changing part for changing a direction of light having entered the light guide section through the light receiving surface and (ii) a transmitting part which transmits light having entered the light guide section through the light receiving surface; the traveling direction changing part has (a) a first inclined surface for reflecting light having entered the light guide section through the light receiving surface and (b) a second inclined surface that is inclined at a smaller angle to the back surface than the first inclined surface is; and the solar cell element is provided on the end face that is closer to the second inclined surface than to the first inclined surface.

According to the configuration, light incident on the traveling direction changing part from the light receiving surface is reflected by the first inclined surface and is collected to the solar cell element. This makes it possible to cause a larger amount of light that has entered the light guide section to be collected to the solar cell element, and thus possible to increase power generation efficiency. Hence, the solar cell module capable of efficient power generation is achieved without having to have the light guide section contain a fluorescent material. This makes it possible to inexpensively and easily produce the solar cell module.

### INDUSTRIAL APPLICABILITY

Since the present invention can provide a solar cell module that provides a high degree of freedom in design and that can be inexpensively and easily produced, the present invention is suitably usable as a solar power generating and heat collecting system provided on windows of buildings, automobile windows, roofs of buildings, etc.

### REFERENCE SIGNS LIST

1 Power generating section
2 Light guide section
3 Solar cell element
4 Heat collecting section
10 Solar cell module
21 Power generating section
22 Light guide section
22a Traveling direction changing part
22b Transmitting part
23 Solar cell element
24 First inclined surface
25 Second inclined surface
31 Power generating section
32 Light guide section
33 Solar cell element
34 Fluorescent material dispersion film
41 Power generating section
42 Light guide section
43 Solar cell element
44 Adhesive layer
45 Light transmissive film

1. A solar cell module comprising:
a power generating section including
a light guide section having a light receiving surface for receiving light from outside, the light guide section being for guiding light received on the light receiving surface and
a solar cell element provided on an end face that intersects the light receiving surface of the light guide section, the solar cell element being for receiving light guided through the light guide section; and
a heat collecting section provided so as to face a back surface opposite to the light receiving surface of the light guide section.

2. The solar cell module as set forth in claim 1, wherein the light guide section has, on at least one surface that intersects the end face on which the solar cell element is provided, a fluorescent layer containing a fluorescent material.

3. The solar cell module as set forth in claim 2, wherein the fluorescent layer is a light transmissive film containing the fluorescent material, the light transmissive film being bonded to said at least one surface of the light guide section via an adhesive layer.

4. The solar cell module as set forth in claim 2, wherein the fluorescent layer is an adhesive layer containing the fluorescent material, with which adhesive layer a light transmissive film is bonded to said at least one surface of the light guide section.

5. The solar cell module as set forth in claim 2, wherein the fluorescent layer is formed by applying a light transmissive material containing the fluorescent material to said at least one surface of the light guide section.

6. The solar cell module as set forth in claim 1, wherein:
the light guide section has, on the back surface opposite to the light receiving surface, (i) a traveling direction changing part for changing a direction of light having entered the light guide section through the light receiving surface and (ii) a transmitting part which transmits light having entered the light guide section through the light receiving surface;
the traveling direction changing part has (a) a first inclined surface for reflecting light having entered the light guide section through the light receiving surface and (b) a second inclined surface that is inclined at a smaller angle to the back surface than the first inclined surface is; and
the solar cell element is provided on the end face that is closer to the second inclined surface than to the first inclined surface.

7. A solar power generating device comprising a solar cell module as set forth in claim 1.
